(19) United States
(12) Patent Application Publication
(10) Pub. No.: US 2023/0120710 A1
(43) Pub. Date: Apr. 20, 2023

(54) DOWNSTREAM RESIDUE MANAGEMENT HARDWARE

(71) Applicant: Applied Materials, Inc., Santa Clara, CA (US)

(72) Inventors: Zaoyuan Ge, San Jose, CA (US); Yin Xiong, Santa Clara, CA (US); Sungwon Ha, Palo Alto, CA (US); Abdul Aziz Khaja, San Jose, CA (US); Amit Bansal, Milpitas, CA (US); Prasath Poomani, Dharmapuri (IN); Ajit Laxman Kulkarni, Vadodara (IN); Sarah Michelle Bobek, Santa Clara, CA (US); Badri N. Ramamurthi, Los Gatos, CA (US)

(73) Assignee: Applied Materials, Inc., Santa Clara, CA (US)

(21) Appl. No.: 17/502,873

(22) Filed: Oct. 15, 2021

(51) Int. Cl. C23C 16/44; H01L 21/02

(52) U.S. Cl. CPC C23C 16/4408; C23C 16/4412; H01L 21/02274

(57) ABSTRACT

Exemplary processing chambers may include a body having sidewalls and a bottom plate. The bottom plate may define an exhaust opening and a gas inlet. The chambers may include a faceplate seated atop the body. The chambers may include a purge ring seated atop the bottom plate. The purge ring may include a ring body having an outer edge and an inner edge defining an open interior. The ring body may have a surface disposed against the bottom plate. The ring body may define an opening aligned with the exhaust opening. The surface may define a fluid port aligned and coupled with the gas inlet. The surface may define arcuate grooves extending into the fluid port. The arcuate grooves may be parallel with the inner and outer edges. The surface may define radial grooves extending from the open interior to an arcuate groove.

### TECHNICAL FIELD

The present technology relates to components and apparatuses for semiconductor manufacturing. More specifically, the present technology relates to processing chamber components and other semiconductor processing equipment.

### BACKGROUND

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies across a substrate may impact the formation or removal process.

Thus, there is a need for improved systems and methods that can be used to produce high quality devices and structures. These and other needs are addressed by the present technology.

### SUMMARY

Exemplary semiconductor processing chambers may include a chamber body having sidewalls and a bottom plate. The bottom plate may define an exhaust opening and at least one purge gas inlet. The chambers may include a faceplate seated atop the chamber body. The chambers may include a purge ring seated atop the bottom plate. The purge ring may include a ring body having an outer edge and an inner edge. The inner edge may define an open interior. The ring body may have a first surface and a second surface opposite the first surface. The second surface may be disposed against a top surface of the bottom plate. The ring body may define an opening between the outer edge and the inner edge. The opening may be aligned with the exhaust opening of the bottom plate. The second surface may define at least one fluid port. Each fluid port may be aligned and fluidly coupled with a respective one of the at least one purge gas inlet. The second surface may define one or more arcuate grooves, each of the arcuate grooves extending into a respective one of the at least one fluid port. The one or more arcuate grooves may be generally parallel with the inner edge and the outer edge of the ring body. The second surface may define a plurality of radial grooves that each extend from the open interior to one of the one or more arcuate grooves.

In some embodiments, the chambers may include a purge source fluidly coupled with the at least one purge gas inlet. The ring body may be generally c-shaped and may include a first end spaced apart from a second end. A gap formed between the first end and the second end may include the opening. The ring body may have an annular shape. The opening may include an aperture that is bounded by a portion of the ring body along an entire outer periphery of the opening. The one or more arcuate grooves may collectively extend around at least 270 degrees about the open interior. The one or more arcuate grooves may form a recursive flow path about the ring body. The radial grooves may collectively extend around at least 270 degrees about the open interior. The radial grooves may be spaced apart at regular angular intervals about the ring body. The chambers may include a foreline, a throttle valve, and a pump that are fluidly coupled with the exhaust opening. The purge ring may include aluminum.

Some embodiments of the present technology may encompass purge rings. The purge rings may include a ring body having an outer edge and an inner edge. The inner edge may define an open interior. The ring body may have a first surface and a second surface opposite the first surface. The ring body may define an opening between the outer edge and the inner edge. The second surface may define at least one fluid port. The second surface may define one or more arcuate grooves. Each of the one or more arcuate grooves may extend into a respective one of the at least one fluid port. The one or more arcuate grooves may be generally parallel with the inner edge and the outer edge of the ring body. The second surface may define a plurality of radial grooves that each extend from the open interior to one of the one or more arcuate grooves.

In some embodiments, the ring body may be generally c-shaped and may include a first end spaced apart from a second end. A gap formed between the first end and the second end may include the opening. The ring body may have an annular shape. The opening may include an aperture that is bounded by a portion of the ring body along an entire outer periphery of the opening. The one or more arcuate grooves may collectively extend around at least 270 degrees about the open interior. The one or more arcuate grooves may form a recursive flow path about the ring body. The radial grooves may collectively extend around at least 270 degrees about the open interior. The radial grooves may be spaced apart at regular angular intervals about the ring body.

Some embodiments of the present technology may encompass methods of processing a substrate. The methods may include flowing a precursor into a processing chamber. The methods may include generating a plasma of the precursor within a processing region of the processing chamber. The methods may include depositing a material on a substrate disposed within the processing region. The methods may include flowing a purge gas through a plurality of grooves formed in a purge ring coupled with a bottom plate of the processing chamber. The plurality of grooves may include one or more arcuate grooves and a plurality of radial grooves. The plurality of radial grooves may direct the purge gas into an open interior of the purge ring.

In some embodiments, the methods may include venting the precursor and the purge gas from the processing chamber via at least one foreline, a throttle valve, and a pump. An inlet opening of the foreline is aligned with the opening of the purge ring. The purge gas may be flowed at a rate of between or about 500 sccm and 10,000 sccm.

Such technology may provide numerous benefits over conventional systems and techniques. For example, embodiments of the present technology may utilize a purge ring coupled with a bottom plate of the chamber body to direct purge gas to lower regions of the processing chamber to prevent and/or remove residue from components of the processing system. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic cross-sectional view of an exemplary processing chamber according to some embodiments of the present technology.

FIGS. 4A-4C shows a schematic views of an exemplary purge ring according to some embodiments of the present technology.

FIG. 5 shows a schematic top plan view of an exemplary purge ring according to some embodiments of the present technology.

FIG. 6 shows a schematic top plan view of an exemplary purge ring installed atop a bottom plate of a chamber body of a processing chamber according to some embodiments of the present technology.

FIG. 7 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

During and/or after processing operations, precursors and/or other process gases may flow into a lower region of the processing chamber. For example, some process gases may flow downward beyond a substrate support during processing operations and/or gases may be vented from the process chamber through a foreline coupled with a bottom of the chamber. Residue caused by radicals from such process gases may collect on lower regions of the chamber body, including a slit valve through which wafers are transferred in and out of the chamber, the lower walls and/or bottom plate of the chamber body, and the venting system, which may include a foreline, throttle valve, and/or pump. These residues necessitate more often and more intensive cleaning of the chamber equipment, which may lead to downtime and service costs. Additionally, the accumulation of residues may lead to shorter service lives of the various components. Additionally, residue accumulation within the throttle valve may reduce the cross-sectional area of the flow path of the throttle valve, which effectively changes the flow conductance through the throttle valve and causes throttle valve drift. For example, over time the accumulation of residue requires the throttle valve to open to a greater degree (drift) to maintain a desired conductance due to the reduction in cross-sectional area of the flow path. This throttle drift changes the cross-sectional area of the flow path associated with each angle of the throttle valve and, over time, requires the throttle valve to be opened to greater angles to account for the decrease in conductance and change in pressure of gases flowing through the throttle valve. At larger angles, the throttle valve becomes more difficult to control to deliver precise conductance and fluid pressures.

The present technology overcomes these challenges by utilizing a purge ring that is affixed to a bottom plate of the chamber body. The purge ring may define a series of grooves that may direct purge gas to a lower region of the chamber body. The purge gas may be flowed during processing operations, which may reduce or prevent the radicals from process gases from forming residue deposits within the lower region. Additionally, the purge gas may remove any residue that that is present. This reduction of residue may reduce the frequency and/or intensity of cleaning operations, and may increase the service life of chamber components. Moreover, the reduction of deposits proximate the slit valve may decrease contamination on wafer during the transfer process. Additionally, embodiments may reduce throttle valve drift and improve flow conductance through the foreline. Accordingly, the present technology may reduce the occurrence of residue deposits within the chamber.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

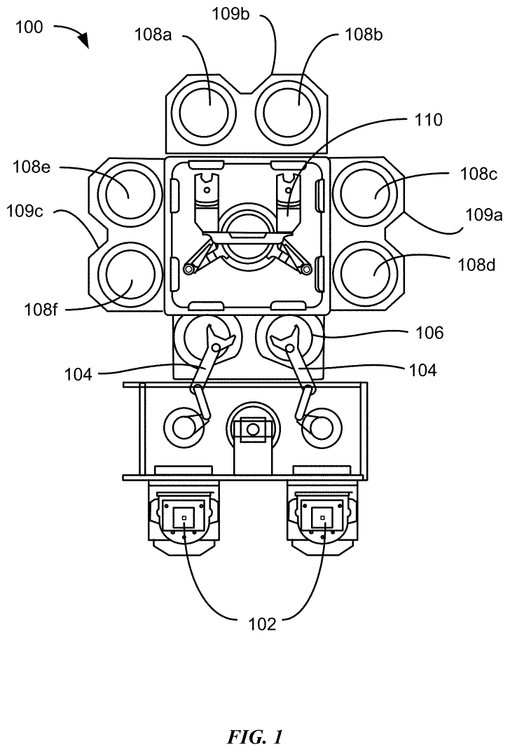

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

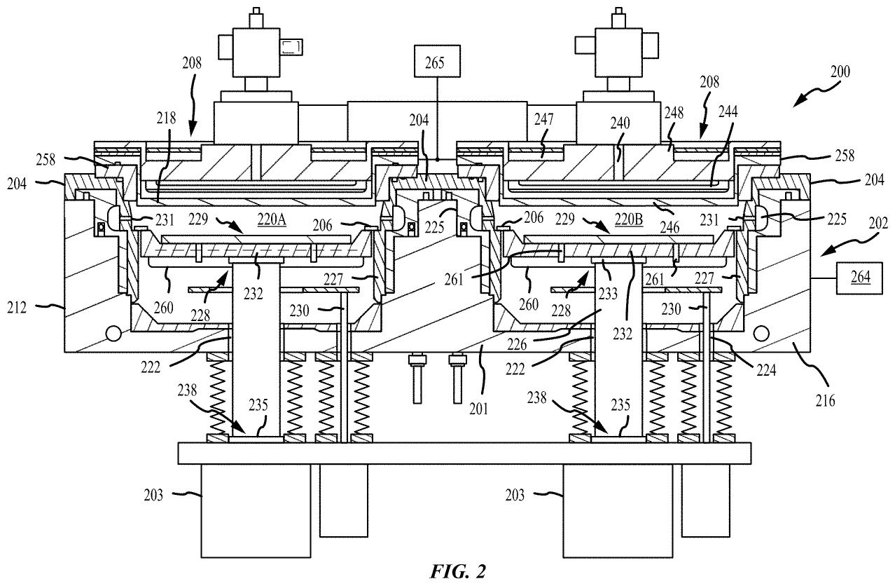

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

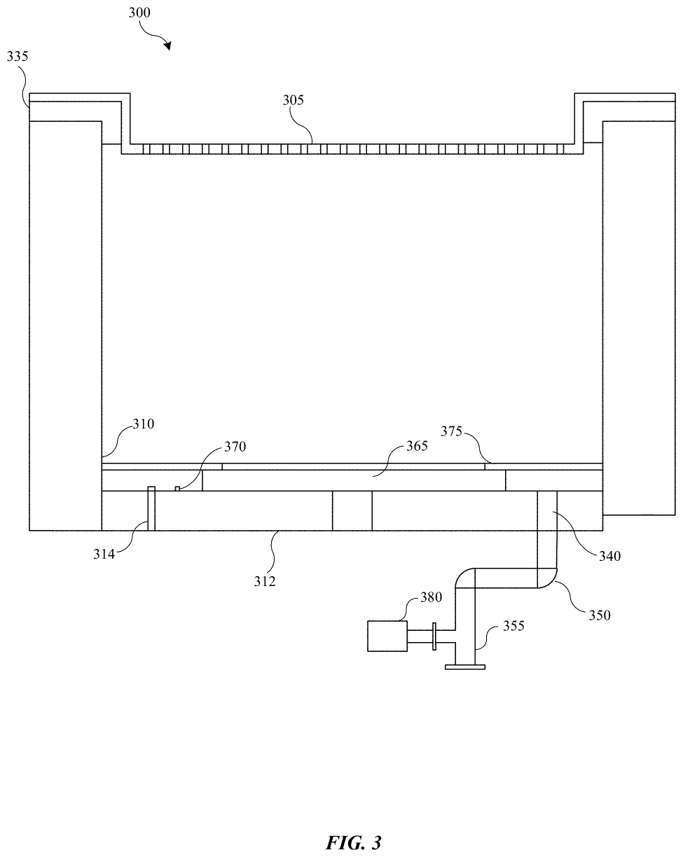

FIG. 3 shows a schematic partial cross-sectional view of an exemplary processing system 300 according to some embodiments of the present technology. FIG. 3 may illustrate further details relating to components in system 200. System 300 is understood to include any feature or aspect of system 200 discussed previously in some embodiments. The system 300 may be used to perform semiconductor processing operations including deposition of hardmask materials as previously described, as well as other deposition, removal, and cleaning operations. System 300 may show a partial view of the chamber components being discussed and that may be incorporated in a semiconductor processing system, and may illustrate a view across a center of the faceplate, which may otherwise be of any size, and include any number of apertures. Any aspect of system 300 may also be incorporated with other processing chambers or systems as will be readily understood by the skilled artisan.

System 300 may include a processing chamber including a faceplate 305, through which precursors may be delivered for processing, and which may be coupled with a power source for generating a plasma within the processing region of the chamber. The chamber may also include a chamber body 310, which as illustrated may include sidewalls and a bottom plate 312 or other base. The faceplate 305 may be supported, either directly or indirectly, by the chamber body 310. As just one example, the faceplate 305 may be supported atop an isolator or other liner 335, which may be seated on a top surface of the chamber body 310. A pedestal or substrate support (not shown) may extend through the bottom plate 312 of the chamber as previously discussed. The substrate support may include a support plate, which may support a semiconductor substrate. The support plate may be coupled with a shaft, which may extend through the bottom plate 312 of the chamber.

The bottom plate 312 may define one or more exhaust openings 340 that enable the flow of gases from the processing region to one or more forelines 350 that are coupled with the processing chamber. For example, each exhaust opening 340 may be fluidly coupled with a top end of one or more of the forelines 350. Each foreline 350 may define a fluid conduit for flowing process gases out of the processing chamber and directing the process gases through a throttle valve 355, which may control the fluid conductance through the forelines 350. A pump 380 may be fluidly coupled with the forelines 350 and the throttle valve 355, and may create a negative pressure that draws gases out of the processing region.

The bottom plate 312 may also define one or more purge gas inlets 314, which may each be aligned with and fluidly coupled with a purge gas source 345, such as via one or more purge gas lumens 347. System 300 may include a purge ring 365 that may be seated atop the bottom plate 312. For example, the purge ring 365 may be seated directly on a top surface of the bottom plate 312 in some embodiments. A lower surface of the purge ring 365 may define a number of grooves 370 that may be fluidly coupled with the purge gas inlets 314. Once the purge ring 365 is coupled with the top surface of the bottom plate 312, the grooves 370 and bottom plate 312 may form purge gas channels that may direct purge gas supplied by purge gas source 345 to an interior portion of the bottom plate 312 to prevent and/or remove residue deposits formed from process gases during deposition and/or other operations. A pumping plate 375 may be positioned atop the purge ring 365 in some embodiments.

The purge ring may direct purge gas to a lower region of the chamber body during processing operations to reduce or prevent the radicals from process gases from forming residue deposits within the lower region. Additionally, the purge gas may remove any residue that that is present. This reduction of residue may reduce the frequency and/or intensity of cleaning operations, and may increase the service life of chamber components. In particular, the purge ring may help reduce solid residue accumulation within the pump and may help extend the operation lifetime of the pump. Moreover, the reduction of deposits proximate a slit valve of the processing chamber may decrease contamination on wafer during the transfer process. Additionally, the flow of purge gas may also reduce throttle valve drift and improve flow conductance through the foreline.

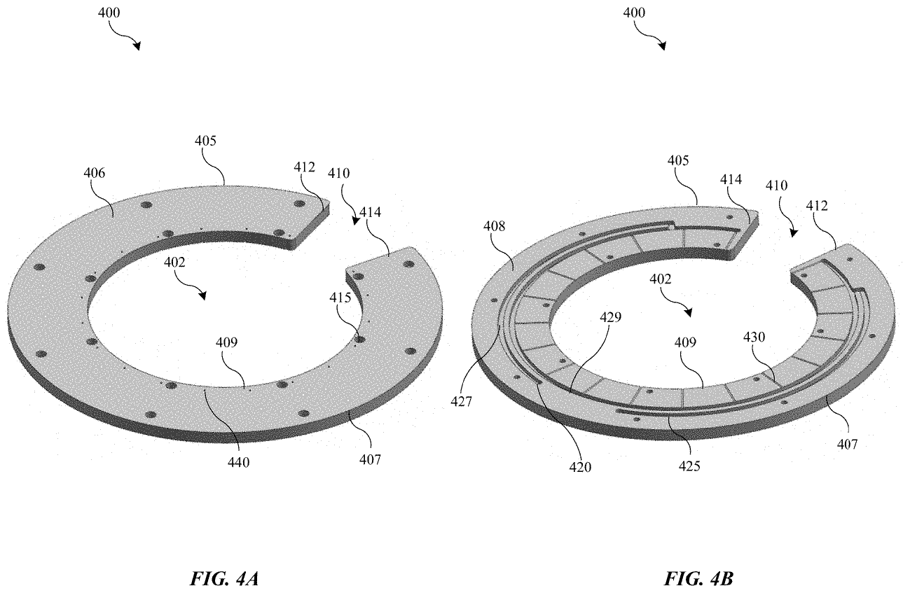

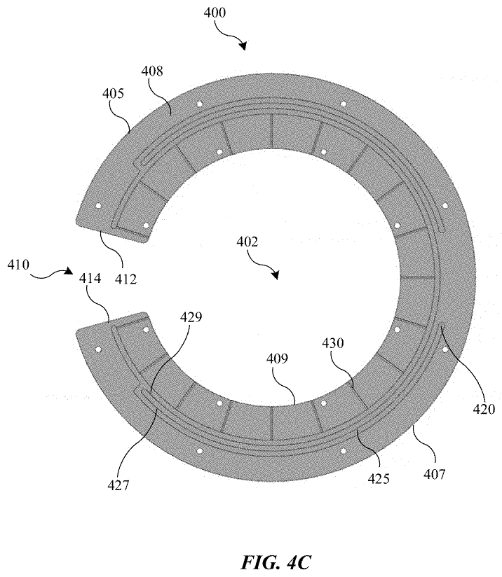

FIGS. 4A-4C show views of an exemplary purge ring 400 according to some embodiments of the present technology. The purge ring 400 may be included in any chamber or system previously described, as well as any other chamber or system that may benefit from the purge ring. For example, the purge ring 400 may be used as purge ring 365 and positioned atop bottom plate 312 as described in relation to FIG. 3. The purge ring 400 may be similar to the purge ring 365 and may include any of the features described in relation to purge ring 365. Purge ring 400 may include a ring body 405, which may be formed from a processing chamber-compatible material such as, but not limited to, aluminum. The ring body 405 may be defined by an outer edge 407 and an inner edge 409, with the inner edge 409 defining an open interior 402 of the purge ring 400. An inner diameter of the ring body 405 (e.g., a diameter of the inner edge 409) may be sufficiently large that a gap is formed between the inner edge 409 and a lateral surface of a shaft of a substrate support disposed within a given processing chamber. Such a gap may leave a generally annular portion of the bottom plate exposed. The ring body 405 may define an opening 410, which may extend between the outer edge 407 and the inner edge 409. The opening 410 may be aligned with an exhaust opening of the bottom plate to enable process and/or purge gases to be vented from the processing chamber through the forelines during and/or after processing operations. In some embodiments, such as illustrated in FIGS. 4A-4C, the opening 410 may be extend entirely through both the inner edge 409 and outer edge 407. For example, the ring body 405 may be generally c-shaped and may include a first end 412 and a second end 414 that are spaced apart by a gap, which forms opening 410.

The ring body 405 may be characterized by a first surface 406 and a second surface 408 that is opposite the first surface 406. When installed within a processing chamber, the first surface 406 may face a processing region of the processing chamber, while the second surface 408 may face and be coupled with the bottom plate of the processing chamber. As best shown in the top isometric view of FIG. 4A, the first surface 406 may be generally uniform in some embodiments, with only a number of apertures 415 being defined therethrough for receiving fastening mechanisms that may be used to couple the purge ring 400 to the bottom plate.

As shown in FIGS. 4B and 4C, the second surface 408 of the ring body 405 may define one or more fluid ports 420 that may be positioned to be aligned with a respective purge gas inlet of the bottom plate. While shown with two fluid ports 420, it will be appreciated that any number of fluid ports 420 may be included in various embodiments, with the number of fluid ports 420 typically matching the number of purge gas inlets defined by the bottom plate. For example, the second surface 408 may define at least or about one fluid port 420, at least or about two fluid ports 420, at least or about three fluid ports 420, at least or about four fluid ports 420, at least or about five fluid ports 420, or more. Second surface 408 may define a number of grooves that may be fluidly coupled with the fluid ports 420 and which may direct purge gas flowed through the fluid ports 420 toward the open interior 402 of the purge ring 400. For example, the second surface 408 may define one or generally arcuate grooves 425. The arcuate grooves 425 may be generally parallel with the inner edge 409 and outer edge 407 of the ring body 405. Each arcuate groove 425 may be fluidly coupled with a respective fluid port 420 and may extend about at least a portion of the open interior 402. In some embodiments, the arcuate grooves 425, individually and/or collectively, may extend around at least or about 270 degrees about the open interior 402, at least or about 285 degrees about the open interior 402, at least or about 300 degrees about the open interior 402, at least or about 315 degrees about the open interior 402, at least or about 330 degrees about the open interior 402, at least or about 345 degrees about the open interior 402, or more, with greater coverage enabling more uniform distribution of purge gas about the open interior 402. Any number of arcuate grooves 425 may be provided, with each arcuate groove 425 extending about at least a portion of the central opening 402. For example, the second surface 408 may define at least or about one arcuate groove 425, at least or about two arcuate grooves 425, at least or about three arcuate grooves 425, at least or about four arcuate grooves 425, at least or about five arcuate grooves 425, or more. As illustrated, a single arcuate groove 425 is defined within the second surface 408, with the single arcuate groove extending about substantially all of the distance between the first end 412 and second end 414, with opposing ends of the arcuate groove 425 each being coupled with a respective one of the fluid port 420. For example, the arcuate groove 425 may extend about at least 75% of the distance between the first end 412 and second end 414, about at least 80% of the distance, at least 85% of the distance, at least about 90% of the distance, at least or about 95% of the distance, at least or about 97% of the distance, or more.

The one or more arcuate grooves 425 may define a recursive flow path that may uniformly distribute purge gas about a substantial portion of the open interior 402 in some embodiments. For example, as illustrated the arcuate groove 425 includes outer regions 427 that each extend from one of the fluid ports 420 about a portion of the open interior 402 in opposite directions (e.g., with one outer region 427 extending in a counterclockwise fashion and the other outer region 427 extending in a clockwise direction) before each coupling with an inner region 429. Inner region may extend about substantially all of the open interior 402 (e.g., greater than or about 270 degrees, 285 degrees, 300 degrees, 315 degrees, 330 degrees, 345 degrees, etc.), which may help uniformly distribute purge gas about a substantial portion of the open interior 402. It will be appreciated that other recursive paths are possible in various embodiments. In some embodiments, a number of distinct arcuate grooves 425 forming a number of recursive patterns and/or arcuate grooves 425 that do not form recursive patterns may be included.

Second surface 408 may define a number of radial grooves 430. Each radial groove 430 may extend between a respective one of the arcuate grooves 425 and the open interior 402. For example, as illustrated, each radial groove 430 extends from the inner region 429 to the open interior 402 to fluidly couple the arcuate groove 425 and fluid port 420 with the open interior 402. Second surface 408 may define any number of radial grooves 430. For example, second surface 408 may define at least or about 5 radial grooves 430, at least or about 10 radial grooves 430, at least or about 15 radial grooves 430, at least or about 20 radial grooves 430, at least or about 25 radial grooves 430, or more, with greater numbers of radial grooves 430 enabling more uniform flow of purge gas about the periphery of the open interior 402. The radial grooves 430 may be provided at regular and/or irregular intervals about the open interior 402. In some embodiments, the radial grooves 430 may extend around at least or about 270 degrees about the open interior 402, at least or about 285 degrees about the open interior 402, at least or about 300 degrees about the open interior 402, at least or about 315 degrees about the open interior 402, at least or about 330 degrees about the open interior 402, at least or about 345 degrees about the open interior 402, or more, with greater coverage enabling more uniform distribution of purge gas about the open interior 402. For example, the radial grooves 430 may span a substantial portion of the distance between the first end 414 and the second end 416. For example, the radial grooves 430 may be distributed about at least 75% of the distance between the first end 412 and second end 414, about at least 80% of the distance, at least 85% of the distance, at least about 90% of the distance, at least or about 95% of the distance, at least or about 97% of the distance, or more.

In some embodiments, the purge gas may be flowed at a rate of between or about 500 sccm and 5000 sccm at each fluid port of the purge ring, between or about 750 and 2500 sccm, or between or about 1000 sccm and 2000 sccm. The flow rate may be dependent on the type of purge gas utilized and/or other process conditions. In some embodiments, the purge gas may include O₂, CO₂, ozone, and/or other cleaning gas.

The purge ring may direct purge gas to a lower region of the chamber body during processing operations to reduce or prevent the radicals from process gases from forming residue deposits within the lower region. Additionally, the purge gas may remove any residue that that is present. This reduction of residue may reduce the frequency and/or intensity of cleaning operations, and may increase the service life of chamber components. Moreover, the reduction of deposits proximate a slit valve of the processing chamber may decrease contamination on wafer during the transfer process. Additionally, the flow of purge gas may also reduce throttle valve drift and improve flow conductance through the foreline. Additionally, the residue reduction of deposition within the throttle valve may reduce the frequency of high temperature purge gas cleanings of the throttle valve, which may help protect chamber components, such as the heater, from such purge gas flows.

In some embodiments, the first surface 406 of the ring body 405 may define one or more purge apertures 440 that may extend through a thickness of the ring body 405. The purge apertures 440 may be fluidly coupled with the grooves formed in the second surface 408. For example, each of the purge apertures 440 may be aligned with and/or otherwise fluidly coupled with a respective one of the radial grooves 430. In some embodiments, each radial groove 430 may include a respective one of the purge apertures 440 such that a number of purge apertures 440 are spaced apart about the open interior 402. In other embodiments, some of the radial grooves 430 may include more than one, or zero, purge apertures 440. In some embodiments, purge apertures 440 may extend into one or more of the arcuate grooves 425. Purge apertures 440 may enable some of the purge gas flowed through the purge ring 400 to be flowed to the first surface 406 of the ring body 405. This purge gas may help prevent residue build up on the surface of the purge ring 400.

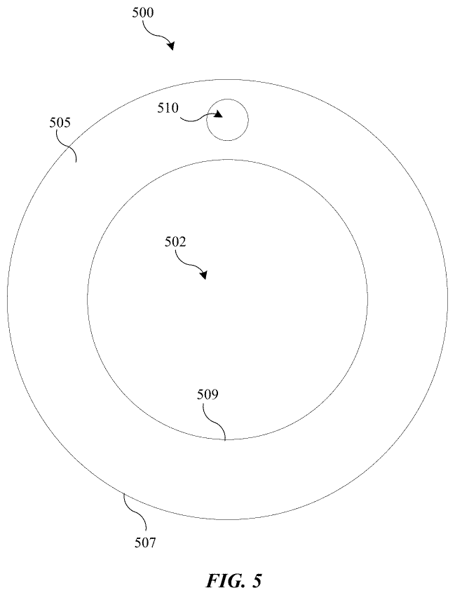

FIG. 5 shows a schematic isometric view of an exemplary purge ring 500 according to some embodiments of the present technology. The purge ring 500 may be included in any chamber or system previously described, as well as any other chamber or system that may benefit from the insert. For example, the purge ring 500 may be disposed atop the bottom plate 312 of the chamber body 310 described above in relation to FIG. 3. Purge ring 500 may be similar to purge rings 365 and 400 and may include any of the features described in relation to purge rings 365 and 400. For example, purge ring 500 may include a ring body 505 that is characterized by a first surface 506 and a second surface (not shown). The ring body 505 may have an annular shape that is characterized by an outer edge 507 and an inner edge 509. The inner edge 509 may define a central opening 502. The second surface may define one or more fluid ports, one or more arcuate grooves, and/or one or more radial grooves (not shown, but may be similar to those shown in FIGS. 4A-4C). Ring body 505 may also define an opening 510 which may extend between the outer edge 507 and the inner edge 509 of the ring body 505. The opening 510 may be aligned with an exhaust opening of the bottom plate to enable process and/or purge gases to be vented from the processing chamber through the forelines during and/or after processing operations. In some embodiments, the opening 510 may be in the form of an aperture through the ring body 505 that is partially and/or fully bounded by a portion of the ring body 505. For example, as illustrated the opening 510 may be a circular (or other shape) aperture having an outer periphery that is fully defined by the ring body 505. The opening 510 may be sized and shaped such that when purge ring 500 is coupled with the bottom plate of the chamber body, the opening 510 provides access to the exhaust opening of the bottom plate to enable gases to be vented from the processing chamber. For example, in some embodiments, the opening 510 may be substantially the same size as the exhaust opening of the bottom plate.

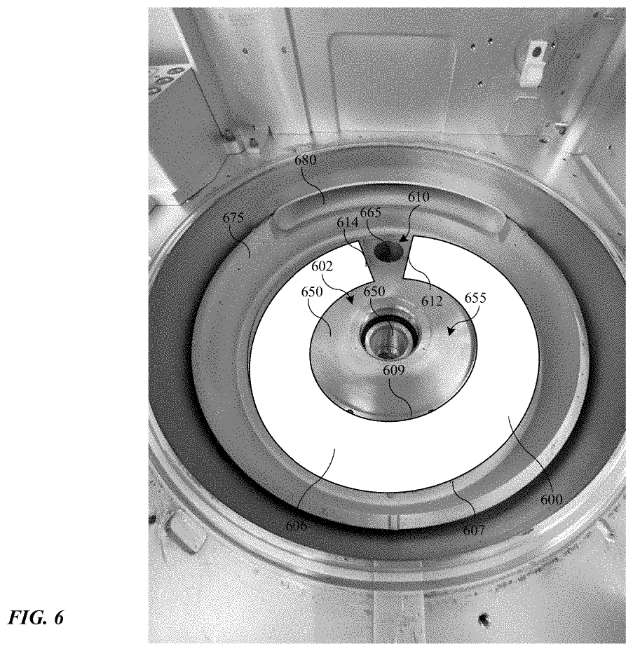

FIG. 6 shows a schematic top plan view of an exemplary purge ring 600 installed atop a bottom plate 650 of a chamber body 675 of a processing chamber according to some embodiments of the present technology. The purge ring 600 and bottom plate 650 may be included in any chamber or system previously described, as well as any other chamber or system that may benefit from the insert. For example, the purge ring 600 may be disposed atop the bottom plate 650 (which may be used as bottom plate 312 of the chamber body 310) as described above in relation to FIG. 3. Bottom plate 650 may be similar to bottom plate 312 and may include any feature described in relation to bottom plate 312. Bottom plate 650 may include a top surface 655 on which the purge ring 600 may be mounted. Bottom plate 650 may define a central aperture 660 that may receive a shaft of a substrate support. Bottom plate 650 may also define an exhaust opening 665, which may be fluidly coupled with a foreline, throttle valve, and/or pump that may be used to vent gases from the processing chamber. The bottom plate 650 may also define one or more purge gas inlets (not shown).

Purge ring 600 may be similar to purge rings 365, 400, and 500 and may include any of the features described in relation to purge rings 365, 400, and 500. For example, purge ring 600 may include a ring body 605 that is characterized by a first surface 606 and a second surface (not shown) that is positioned against a top surface 655 of the bottom plate 650. The ring body 605 may be characterized by an outer edge 607 and an inner edge 609, with the inner edge 609 defining an open interior 602 of the ring body 605. As illustrated, the ring body 605 may be generally c-shaped and may include a first end 612 and a second end 614 that are spaced apart by a gap, which forms an opening 610. The opening 610 may be aligned with exhaust opening 665 of the bottom plate 650 to enable process and/or purge gases to be vented from the processing chamber through the forelines during and/or after processing operations. The second surface of the purge ring 600 may define a number of fluid ports that are fluidly coupled with a number of grooves, such as one or more arcuate grooves and a number of radial grooves (similar to those described above). The fluid ports and grooves may form a fluid path that directs purge gas flowed through the purge gas inlets of the bottom plate 650 toward the open interior 602. The purge gas may prevent and/or remove residues deposited on the top surface 655 of the bottom plate 650, as well as other downstream components (e.g., the forelines, throttle valve, pump, etc.) and/or a slit valve 680 formed in the chamber body 675 and used for transferring substrates in and out of the processing chamber.

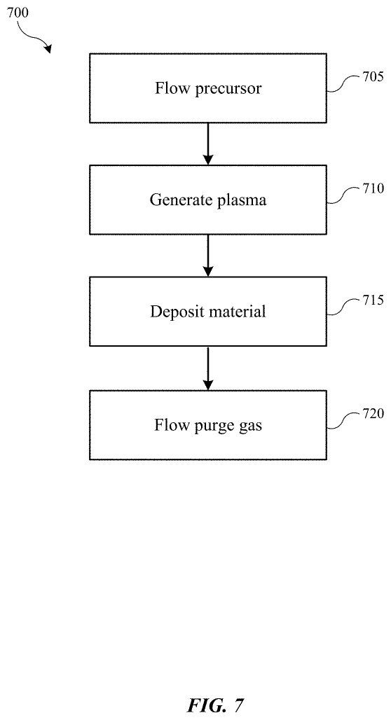

FIG. 7 illustrates operations of an exemplary method 700 of semiconductor processing according to some embodiments of the present technology. The method may be performed in a variety of processing chambers, including processing system 200 and/or 300 described above, which may include purge rings and/or bottom plates according to embodiments of the present technology, such as purge rings 365, 400, 500, and 600 and/or bottom plates 312 and 650. Method 700 may include a number of optional operations, which may or may not be specifically associated with some embodiments of methods according to the present technology.

Method 700 may include a processing method that may include operations for forming a hardmask film or other deposition operations. The method may include optional operations prior to initiation of method 700, or the method may include additional operations. For example, method 700 may include operations performed in different orders than illustrated. In some embodiments, method 700 may include flowing one or more precursors or other process gases into a processing chamber at operation 705. For example, the precursor may be flowed into a chamber, such as included in system 200 or 300, and may flow the precursor through one or more of a gasbox, a blocker plate, or a faceplate, prior to delivering the precursor into a processing region of the chamber.

At operation 710, a plasma may be generated of the precursors within the processing region, such as by providing RF power to the faceplate to generate a plasma. Material formed in the plasma may be deposited on the substrate at operation 715. At operation 720, a purge gas may be flowed into the processing chamber via a number of grooves formed in a purge ring that is coupled with a bottom plate of the chamber body of the processing chamber. For example, the purge gas may be flowed from a purge gas source through one or more purge gas inlets formed in the bottom plate. The purge gas may then flow into fluid ports formed in the purge ring, with the grooves directing the purge gas into an open interior of the purge ring. The purge gas may prevent and/or remove residue from process gases that flow into the lower region of the processing chamber. The prevention and/or removal of such residue may help extend the service life of various chamber components, including the foreline, throttle valve, and pump. The reduction in residue formation may also occur proximate a slit valve of the chamber body, which may help reduce contamination of wafers as the wafers are transferred in and out of the processing chamber. In some embodiments, the purge gas may be flowed at a rate of between or about 500 sccm and 10,000 sccm (cumulatively through all fluid ports of the purge ring), with the flow rate being dependent on what type of purge gas is used and/or other process conditions. In some embodiments, the purge gas may include O₂, CO₂, ozone, and/or other cleaning gas. In some embodiments, the purge gas may be flowed after a processing operation to clean any residue formed within a lower region of the processing chamber.

In some embodiments, the method 700 may include venting the precursor and the purge gas from the processing chamber via at least one foreline, a throttle valve, and a pump. The gases may pass through an exhaust opening formed in the bottom plate prior to reaching the foreline. The presence of the purge gas within the foreline may prevent and/or remove residue from the foreline, a throttle valve, and pump. The reduction in residue within the throttle valve may help maintain proper conductance through the throttle valve and reduce the amount of throttle valve drift, which in turn may reduce the frequency of cleaning operations.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing chamber, comprising:
a chamber body having sidewalls and a bottom plate, the bottom plate defining an exhaust opening and at least one purge gas inlet;
a faceplate seated atop the chamber body; and
a purge ring seated atop the bottom plate, the purge ring comprising:
a ring body having an outer edge and an inner edge, the inner edge defining an open interior, wherein:
the ring body has a first surface and a second surface opposite the first surface;
the second surface is disposed against a top surface of the bottom plate;
the ring body defines an opening between the outer edge and the inner edge;
the opening is aligned with the exhaust opening of the bottom plate;
the second surface defines at least one fluid port, with each fluid port being aligned and fluidly coupled with a respective one of the at least one purge gas inlet;
the second surface defines one or more arcuate grooves, each of the arcuate grooves extending into a respective one of the at least one fluid port;
the one or more arcuate grooves are generally parallel with the inner edge and the outer edge of the ring body; and
the second surface defines a plurality of radial grooves that each extend from the open interior to one of the one or more arcuate grooves.

2. The semiconductor processing chamber of claim 1, further comprising:
a purge source fluidly coupled with the at least one purge gas inlet.

3. The semiconductor processing chamber of claim 1, wherein:
the ring body is generally c-shaped and comprises a first end spaced apart from a second end; and
a gap formed between the first end and the second end comprises the opening.

4. The semiconductor processing chamber of claim 1, wherein:
the ring body has an annular shape; and
the opening comprises an aperture that is bounded by a portion of the ring body along an entire outer periphery of the opening.

5. The semiconductor processing chamber of claim 1, wherein:
the one or more arcuate grooves collectively extend around at least 270 degrees about the open interior.

6. The semiconductor processing chamber of claim 1, wherein:
the one or more arcuate grooves form a recursive flow path about the ring body.

7. The semiconductor processing chamber of claim 1, wherein:
the radial grooves collectively extend around at least 270 degrees about the open interior.

8. The semiconductor processing chamber of claim 1, wherein:
the radial grooves are spaced apart at regular angular intervals about the ring body.

9. The semiconductor processing chamber of claim 1, further comprising:
a foreline, a throttle valve, and a pump that are fluidly coupled with the exhaust opening.

10. The semiconductor processing chamber of claim 1, wherein:
the purge ring comprises aluminum.

11. A purge ring, comprising:
a ring body having an outer edge and an inner edge, the inner edge defining an open interior, wherein:
the ring body has a first surface and a second surface opposite the first surface;
the ring body defines an opening between the outer edge and the inner edge;
the second surface defines at least one fluid port;
the second surface defines one or more arcuate grooves, each of the one or more arcuate grooves extending into a respective one of the at least one fluid port;
the one or more arcuate grooves are generally parallel with the inner edge and the outer edge of the ring body; and
the second surface defines a plurality of radial grooves that each extend from the open interior to one of the one or more arcuate grooves.

12. The purge ring of claim 11, wherein:
the ring body is generally c-shaped and comprises a first end spaced apart from a second end; and
a gap formed between the first end and the second end comprises the opening.

13. The purge ring of claim 11, wherein:
the ring body has an annular shape; and
the opening comprises an aperture that is bounded by a portion of the ring body along an entire outer periphery of the opening.

14. The purge ring of claim 11, wherein:
the one or more arcuate grooves collectively extend around at least 270 degrees about the open interior.

15. The purge ring of claim 11, wherein:
the one or more arcuate grooves form a recursive flow path about the ring body.

16. The purge ring of claim 11, wherein:
the radial grooves collectively extend around at least 270 degrees about the open interior.

17. The purge ring of claim 11, wherein:
the radial grooves are spaced apart at regular angular intervals about the ring body.

18. A method of processing a substrate;
flowing a precursor into a processing chamber;
generating a plasma of the precursor within a processing region of the processing chamber;
depositing a material on a substrate disposed within the processing region; and
flowing a purge gas through a plurality of grooves formed in a purge ring coupled with a bottom plate of the processing chamber, the plurality of grooves comprising one or more arcuate grooves and a plurality of radial grooves, wherein the plurality of radial grooves direct the purge gas into an open interior of the purge ring.

19. The method of processing a semiconductor substrate of claim 18, further comprising:
venting the precursor and the purge gas from the processing chamber via at least one foreline, a throttle valve, and a pump, wherein an inlet opening of the foreline is aligned with the opening of the purge ring.

20. The method of processing a semiconductor substrate of claim 18, wherein:
the purge gas is flowed at a rate of between or about 500 sccm and 10,000 sccm.
